(19) United States
(12) Patent Application Publication
(10) Pub. No.: US 2024/0356508 A1
(43) Pub. Date: Oct. 24, 2024

(54) CAPACITIVELY COUPLED CHOPPER INSTRUMENTATION AMPLIFIER AND CONTROL METHOD THEREOF

(71) Applicant: TRITIUM ELECTRONICS PTE. LTD., SG (SG)

(72) Inventor: Zhi-Xin Chen, Hsinchu (TW)

(21) Appl. No.: 18/454,047

(22) Filed: Aug. 22, 2023

(30) Foreign Application Priority Data
Apr. 20, 2023 (CN) 202310429618.9

(51) Int. Cl. H03F 3/45; H03F 1/34

(52) U.S. Cl. CPC H03F 3/45475; H03F 1/342; H03F 2200/261; H03F 2200/271

(57) ABSTRACT

A capacitively coupled chopper instrumentation amplifier includes: an input chopper unit, configured to chop a differential input signal based on a clock signal to generate a chopped differential input signal; an output chopper unit, configured to chop a differential output signal based on the clock signal to generate a chopped differential output signal; a capacitor feedback network, configured to convert a differential difference of the chopped differential output signal and the chopped differential input signal to generate a differential feedback signal by a switching capacitor division voltage method with the input chopper unit and the output chopper unit; and a fully differential amplifier, which is configured to amplify the differential feedback signal to generate a differential output signal; wherein, in an initial period after the input chopper unit receives a differential input signal, the capacitively coupled chopper instrumentation amplifier prevents an output saturation by reducing a gain.

### CROSS REFERENCE

The present invention claims priority to CN 202310429618.9 filed on Apr. 20, 2023.

### BACKGROUND OF THE INVENTION

### Field of Invention

The present invention relates to a capacitively coupled chopper instrumentation amplifier, in particular to a capacitively coupled chopper instrumentation amplifier which avoids output saturation by reducing the gain during an initial period. The present invention also relates to a control method of a capacitively coupled chopper instrumentation amplifier.

### Description of Related Art

FIG. 1 shows a schematic diagram of a prior art capacitively coupled chopper instrumentation amplifier. As shown in FIG. 1, the capacitively coupled chopper instrumentation amplifier 100 includes an input chopping unit CHin, a feedback chopping unit CHfb, a capacitor feedback network Cnet1 and a fully differential amplifier Amp1. The capacitor feedback network Cnet1 includes capacitors C11, C12, C21 and C22. In general, the capacitively coupled chopper instrumentation amplifier 100 is used in a high-precision and low-noise signal sense amplifier circuit. In a general operation, especially when the capacitively coupled chopper instrumentation amplifier 100 operates in a high voltage above 20 volts, it is a long time from a relatively high DC offset level to a stable predetermined output level during an initial period of the general operation. For example, the capacitively coupled chopper instrumentation amplifier 100 is applied to a voltage sensing circuit of a high-voltage battery. During the initial period, when a battery voltage is just connected to the capacitively coupled chopper instrumentation amplifier circuit 100, a DC offset at an input due to the battery voltage will cause a large DC offset at an output, causing the output of the capacitively coupled chopper instrumentation amplifier circuit 100 to saturate and require a long time for the signal recovery.

In view of this, the present invention is aimed at the deficiencies of the above-mentioned conventional art, and proposes a capacitively coupled chopper instrumentation amplifier and its control method, which can shorten the time period to reach the predetermined output voltage in the initial period. It greatly improves the operation speed of the capacitively coupled chopper instrumentation amplifier during the initial period of receiving the input signal or during the initial period of switching the channel for receiving the signal, and is suitable for application in a high-precision high-voltage battery voltage signal sensing system.

### SUMMARY OF THE INVENTION

The present invention provides a capacitively coupled chopper instrumentation amplifier, comprising: an input chopping unit, which is configured to operably chop a differential input signal based on a clock signal to generate a chopped differential input signal; a feedback chopping unit, which is configured to operably chop a differential output signal based on the clock signal to generate a chopped differential feedback signal; a capacitor feedback network, which includes a pair of differential input capacitors and a pair of differential feedback capacitors, wherein each of the differential input capacitors is connected to a corresponding one of the differential: feedback capacitors in series between the input chopping unit and the feedback chopping unit, wherein the input chopping unit, the feedback chopping unit, and the capacitor feedback network are coupled to convert a differential difference of the chopped differential output signal and the chopped differential input signal to generate a differential feedback signal by a switching capacitor voltage division method; and a fully differential amplifier, which is configured to operably amplify the differential feedback signal to generate the differential output signal; wherein a gain between the differential output signal and the differential input signal is equal to twice a differential input capacitance of the differential input capacitor divided by a differential feedback capacitance of the differential feedback capacitor; wherein during a normal operation, the gain is a predetermined gain, the differential input capacitance is a predetermined differential input capacitance, and the differential feedback capacitance is a predetermined differential feedback capacitance; wherein during an initial period, when the input chopping unit receives the differential input signal, the capacitively coupled chopper instrumentation amplifier avoids an output saturation of the capacitively coupled chopper instrumentation amplifier by reducing the gain to an adjusted gain.

The present invention provides a control method of a capacitively coupled chopper instrumentation amplifier, comprising steps of: chopping a differential input signal based on a clock signal to generate a chopped differential input signal; chopping a differential output signal based on the clock signal to generate a chopped differential feedback signal; providing a pair of differential input capacitors and a pair of differential feedback capacitors, wherein each of the differential input capacitors is connected to a corresponding one of the differential feedback capacitors in series, and converting a differential difference of the chopped differential output signal and the chopped differential input signal to generate a differential feedback signal by a switching capacitor voltage division method; and avoiding output saturation of the capacitively coupled chopper instrumentation amplifier by reducing a gain to an adjusted gain between the differential output signal and the differential input signal during an initial period; wherein the gain is equal to twice a differential input capacitance of the differential input capacitor divided by a differential feedback capacitance of the differential feedback capacitor; wherein during a normal operation, the gain is a predetermined gain, the differential input capacitance is a predetermined differential input capacitance, and the differential feedback capacitance is a predetermined differential feedback capacitance.

In one embodiment, the capacitively coupled chopper instrumentation amplifier further includes a common-mode circuit which is coupled to the capacitor feedback network, and is configured to operably regulate a common-mode voltage of the differential feedback signal to a predetermined common-mode voltage.

In one embodiment, the capacitively coupled chopper instrumentation amplifier reduces the gain during the initial period by reducing the differential input capacitance and/or increasing the differential feedback capacitance.

In one embodiment, the capacitively coupled chopper instrumentation amplifier further includes: a switch circuit, which is configured to operably switch a plurality of switches therein during the initial period according to a timing control signal, so as to switch electrical connection states of a first input capacitor and a second input capacitor of each of the differential input capacitor between the input chopping unit and the corresponding differential feedback capacitor, thereby reducing the gain during the initial period; and a switch control circuit, which is configured to operably generate the timing control signal to control the switch circuit.

In one embodiment, the plurality of switches includes: a pair of first switches, wherein each of the first switches is coupled between the predetermined common-mode voltage and a corresponding common-mode input terminal; a pair of second switches, wherein each of the second switches is coupled between a corresponding differential feedback terminal and a corresponding differential output terminal; a pair of inverse second switches, wherein each of the inverse second switches is coupled between the corresponding differential feedback terminal and the corresponding common-mode input terminal, wherein the inverse second switch and the second switch operate inversely to each other; a pair of third switches, wherein each of the third switches is coupled between the predetermined common-mode voltage and a second side of the corresponding first input capacitor opposite to a first side coupled to the input chopping unit; and a pair of fourth switches, wherein each of the fourth switches is coupled between the corresponding second side and the corresponding common-mode input terminal.

In one embodiment, the initial period includes: a first phase, wherein both the input chopping unit and the feedback chopping unit keep forward conduction, and the switch control circuit controls the pair of the first switches to be turned ON, the pair of the second switches to be turned ON, the pair of the third switches to be turned ON, and the pair of the fourth switches to be turned OFF through the timing control signal, so as to sample and hold the differential input signal in the pair of differential input capacitors, and reset the differential feedback capacitance; a second phase, wherein the input chopping unit switches to cross conduction, the feedback chopping unit keeps forward conduction, and the switch control circuit controls the pair of the first switches to be switched OFF, the pair of the second switches to be switched OFF, the pair of the third switches to be kept ON, and the pair of the fourth switches to be kept OFF through the timing control signal, so that the adjusted gain is twice a second input capacitance of the second input capacitor divided by the differential feedback capacitance; and a third phase, wherein the input chopping unit keeps cross conduction, the feedback chopping unit keeps forward conduction, and the switch control circuit controls the pair of the first switches to be kept OFF, the pair of the second switches to be kept OFF, the pair of the third switches to be switched OFF through the timing control signal, and the pair of the fourth switches is switched ON after the pair of third switches is switched OFF, so as to electrically connect the first input capacitor and the second input capacitor in parallel to form the differential input capacitance to end the initial period to start the normal operation; wherein the adjusted gain in the initial period is lower than the predetermined gain, so as to avoid the output saturation of the capacitively coupled chopper instrumentation amplifier.

In one embodiment, after the end of the first phase, during the beginning of the second phase, there is a dead time after forward conduction and before switching to cross conduction of the input chopping unit.

In one embodiment, in the third phase, the switch control circuit ends the initial period after the capacitively coupled chopper instrumentation amplifier circuit operates in a steady state to start the normal operation.

In one embodiment, in the initial period, the adjusted gain is equal to half of the predetermined gain.

In one embodiment, the capacitively coupled chopper instrumentation amplifier of claim 3, further comprising: a switch circuit, which is configured to operably switch a plurality of switches therein according to a timing control signal, so as to switch electrical connection states of a first feedback capacitor and a second feedback capacitor of each of the differential feedback capacitor between the feedback chopping unit and the corresponding differential input capacitor during the initial period, thereby reducing the gain; and a switch control circuit, which is configured to operably generate the timing control signal to control the switch circuit.

In one embodiment, the plurality of switches includes: a pair of first switches, wherein each of the first switches is coupled between the predetermined common-mode voltage and a corresponding common-mode input terminal; a pair of second switches, wherein each of the second switches is coupled between a corresponding differential feedback terminal and a corresponding differential output terminal; a pair of inverse second switches, wherein each of the inverse second switches is coupled between the corresponding differential feedback terminal and the corresponding common-mode input terminal, wherein the inverse second switch and the second switch operate inversely to each other; a pair of third switches, wherein each of the third switches is coupled between the predetermined common-mode voltage and a second side of the corresponding first feedback capacitor opposite to the first side coupled to the differential feedback terminal; and a pair of fourth switches, wherein each of the fourth switches is coupled between the corresponding second side and the corresponding common-mode input terminal.

In one embodiment, the initial period comprises: a first phase, wherein both the input chopping unit and the feedback chopping unit keep forward conduction, and the switch control circuit controls the pair of first switches to be turned ON, the pair of second switches to be turned ON, the pair of third switches to be turned ON, and the pair of fourth switches to be turned OFF through the timing control signal, so as to sample and hold the differential input signal in the pair of differential input capacitors, and reset the differential feedback capacitance; a second phase, wherein the input chopping unit switches to cross conduction, the feedback chopping unit keeps forward conduction, and the switch control circuit controls the pair of the first switches to be switched OFF, the pair of the second switches to be switched OFF, the pair of the third switches to be kept ON, and the pair of the fourth switches switched to be switched ON through the timing control signal, so as to electrically connect the second feedback capacitor with the first feedback capacitor in parallel, and the adjusted gain is twice the differential input capacitance divided by the differential feedback capacitance after the second feedback capacitance is electrically connected in parallel with the first feedback capacitance; and a third phase, wherein the input chopping unit keeps cross conduction, the feedback chopping unit keeps forward conduction, and the switch control circuit controls the pair of the first switches to be kept OFF, the pair of the second switches to be kept OFF, the pair of the third switches to be switched OFF, and the pair of the fourth switches to be switched OFF through the timing control signal, so as to end the parallel connection between the second feedback capacitor and the first feedback capacitor, and end the initial period to start the normal operation; wherein the adjusted gain in the initial period is lower than the predetermined gain, so as to avoid the output saturation of the capacitively coupled chopper instrumentation amplifier.

In one embodiment, after the end of the first phase, during the beginning of the second phase, there is a dead time after forward conduction and before switching to cross conduction of the input chopping unit.

In one embodiment, in the third phase, the switch control circuit ends the initial period after the capacitively coupled chopper instrumentation amplifier circuit operates in a steady state to start the normal operation.

In one embodiment, in the initial period, the adjusted gain is equal to half of the predetermined gain.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a schematic diagram of a capacitively coupled chopper instrumentation amplifier of a conventional art.

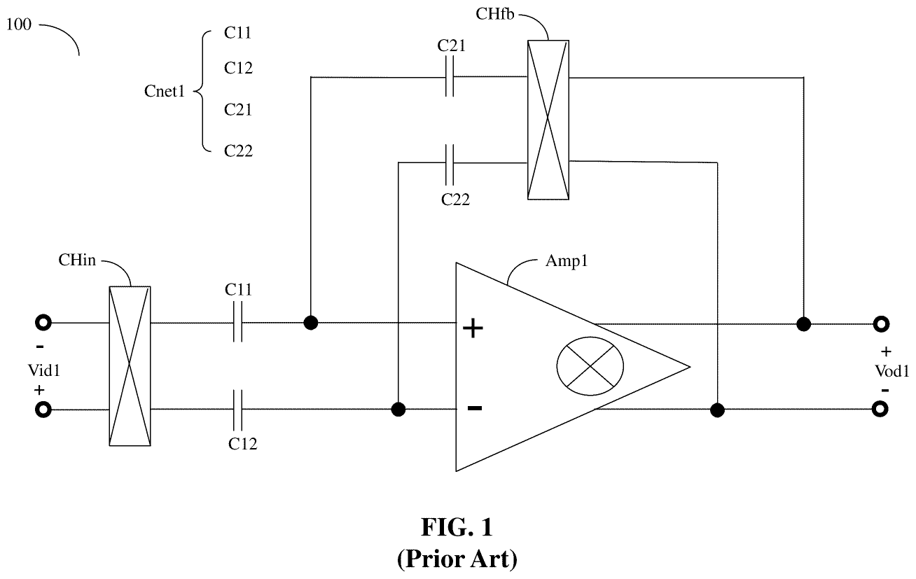

FIG. 2 shows a schematic diagram of a capacitively coupled chopper instrumentation amplifier according to an embodiment of the present invention.

FIG. 3 shows signal waveform diagram of a differential input signal Vid1 and a differential output signal Vod1 of a capacitively coupled chopper instrumentation amplifier of a conventional art and a differential input signal Vid2 and a differential output signal Vod2 of a capacitively coupled chopper instrumentation amplifier according to the present invention.

FIG. 4 shows a schematic diagram of a capacitively coupled chopper instrumentation amplifier according to an embodiment of the present invention.

FIG. 5 shows a schematic diagram of relevant signal waveforms of a capacitively coupled chopper instrumentation amplifier during an initial period according to an embodiment of the present invention.

FIG. 6 shows a schematic diagram of a capacitively coupled chopper instrumentation amplifier according to an embodiment of the present invention.

FIG. 7 shows a schematic diagram of relevant signal waveforms of a capacitively coupled chopper instrumentation amplifier during an initial period according to an embodiment of the present invention.

### DESCRIPTION OF THE PREFERRED EMBODIMENTS

The drawings as referred to throughout the description of the present invention are for illustration only, to show the interrelations between the circuits and the signal waveforms, but not drawn according to actual scale.

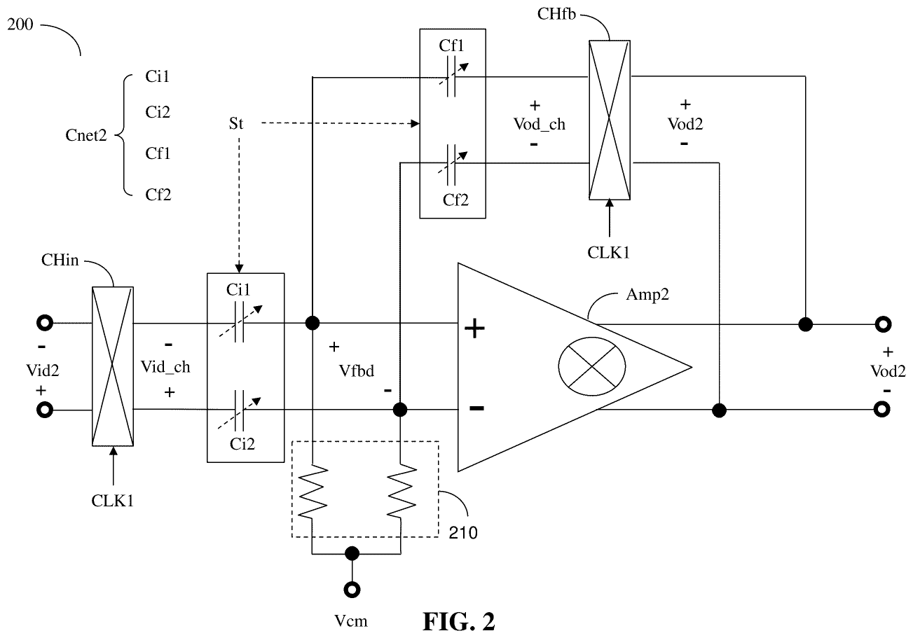

Please refer to FIG. 2. FIG. 2 is a schematic diagram of a capacitively coupled chopper instrumentation amplifier according to an embodiment of the present invention. As shown in FIG. 2, the capacitively coupled chopper instrumentation amplifier 200 includes an input chopping unit CHin, a feedback chopping unit CHfb, a capacitor feedback network Cnet2 and a fully differential amplifier Amp2.

The input chopping unit CHin is used for chopping a differential input signal Vid2 based on a clock signal CLK1 to generate a chopped differential input signal Vid_ch. The feedback chopping unit CHfb is used for chopping a differential output signal Vod2 based on the clock signal CLK1 to generate a chopped differential feedback signal Vod_ch. The capacitor feedback network Cnet2 includes a pair of differential input capacitors Ci1, Ci2 and a pair of differential feedback capacitors Cf1, Cf2, wherein the differential input capacitors Ci1 and Ci2, and the differential feedback capacitors Cf1 and Cf2 are connected in series respectively between the input chopping unit CHin and the feedback chopping unit CHfb as shown in FIG. 2. The differential input capacitor Ci1 and the differential feedback capacitor Cf1 are connected in series between the input chopping unit CHin and the feedback chopping unit CHfb. The differential input capacitor Ci2 and the differential feedback capacitor Cf2 are connected in series between the input chopping unit CHin and the feedback chopping unit CHfb. The input chopping unit CHin, the feedback chopping unit CHfb, and the capacitor feedback network Cnet2 are used to convert a differential difference of the chopped differential feedback signal Vod_ch and the chopped differential input signal Vid_ch to generate a differential feedback signal Vfbd by a switching capacitor voltage division method. The switching capacitor voltage division method (with a switched-capacitor voltage divider) is well known to those skilled in this art and therefore is not redundantly explained here.

The fully differential amplifier Amp2 is used to amplify the differential feedback signal Vfbd to generate the differential output signal Vod2 The gain between the differential output signal Vod2 and the differential input signal Vid2 is equal to twice the differential input capacitance of the differential input capacitors Ci1, Ci2 (differential input capacitor Ci1 and the differential input capacitor Ci2 are a same type capacitor, and have a same differential input capacitance) divided by the differential feedback capacitance of the differential feedback capacitors Cf1, Cf2 (differential feedback capacitor Cf1 and differential feedback capacitor Cf2 are a same type capacitor, and have a same differential feedback capacitance). During a normal operation, the gain is a predetermined gain, the differential input capacitance is a predetermined differential input capacitance, and the differential feedback capacitance is a predetermined differential feedback capacitance. During the initial period when the input chopping unit CHin receives the differential input signal Vid2, the capacitively coupled chopper instrumentation amplifier 200 reduces the gain to an adjusted gain between the differential output signal Vod2 and the differential input signal Vid2 to avoid output saturation of the capacitively coupled chopper instrumentation amplifier 200.

In one embodiment, the capacitively coupled chopper instrumentation amplifier 200 further includes a common-mode circuit 210 coupled to the capacitor feedback network Cnet2. The common-mode circuit 210 is, for example, coupled between the differential input capacitors Ci1 and Ci2 and the differential feedback capacitors Cf1 and Cf2 for regulating a common-mode voltage of the differential feedback signal Vfbd to a predetermined common-mode voltage. The common-mode circuit 210 includes, for example but not limited to, resistors connected in parallel as shown in FIG. 2, and is coupled to the predetermined common-mode voltage Vcm. The common-mode circuit 210 can also be provided with a predetermined common-mode voltage Vcm by a fixed voltage source, which is well known to those skilled in the art and will not be repeated here. In addition, the common-mode circuit 210 can also include a switched capacitor, a switched resistor or a common-mode feedback circuit, and these circuits can all serve as the common-mode circuit 210.

In one embodiment, the capacitively coupled chopper instrumentation amplifier 200 reduces the gain to the adjusted gain between the differential output signal Vod2 and the differential input signal Vid2 during the initial period by reducing the differential input capacitance and/or increasing the differential feedback capacitance to avoid output saturation of the capacitively coupled chopper instrumentation amplifier 200.

In one embodiment, the capacitively coupled chopper instrumentation amplifier 200 reduces the differential input capacitance and/or increases the differential feedback capacitance to reduce the gain to the adjusted gain between the differential output signal Vod2 and the differential input signal Vid2 through the timing control signal St shown in FIG. 2, so as to avoid output saturation of the capacitively coupled chopper instrumentation amplifier 200. The embodiment will be described in detail later.

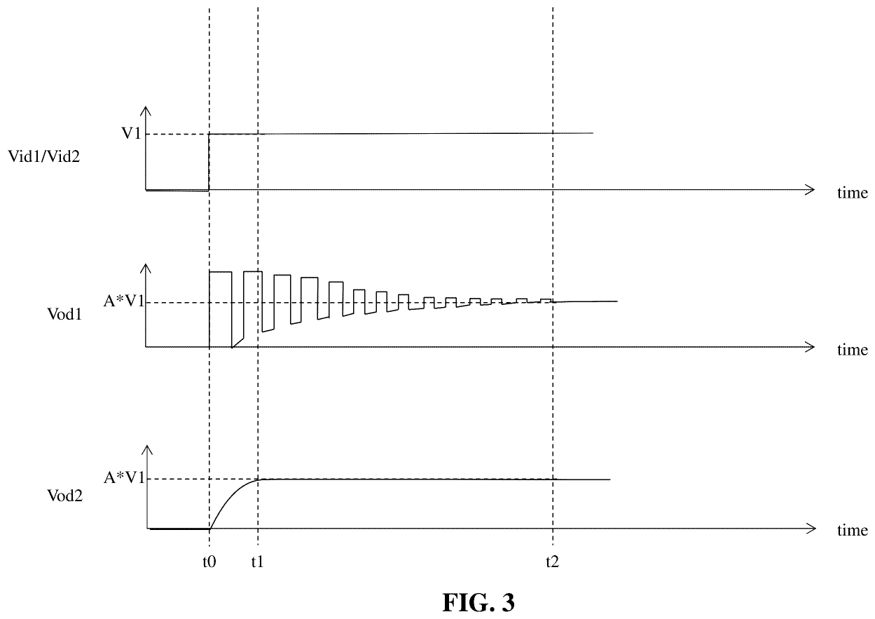

FIG. 3 is a schematic diagram showing signal waveforms of a differential input signal Vid1 and a differential output signal Vod1 of a prior art capacitively coupled chopper instrumentation amplifier and signal waveforms of a differential input signal Vid2 and a differential output signal Vod2 of a capacitively coupled chopper instrumentation amplifier according to the present invention. As shown in FIG. 3, at a time point to, the differential input signal Vid1 of the prior art and the differential input signal Vid2 according to the present invention are both switched from zero voltage to voltage V1. When the prior art capacitively coupled chopper instrumentation amplifier 100 for example is applied in a voltage sensing circuit for sensing voltage of a high-voltage battery, and when a battery voltage is applied to the capacitively coupled chopper instrumentation amplifier circuit 100 during the initial period, due to a DC offset caused by the battery voltage, a huge DC offset will be generated in an output of the capacitively coupled chopper instrumentation amplifier circuit 100, thereby causing the output of the capacitively coupled chopper instrumentation amplifier 100 to be saturated as shown in the signal waveform of the differential output signal Vod1 in FIG. 3. Moreover, it needs to wait for a relatively long time, until time point t2, for the differential output signal Vod1 to reach a stable predetermined level A*V1, where A is a predetermined gain of the capacitively coupled chopper instrumentation amplifier 100 during the normal operation, that is, during the normal operation, the differential output signal Vod1 divided by the differential input signal Vid1 is equal to A, wherein the differential output signal Vod2 divided by the differential input signal Vid2 is also equal to A.

In contrast, the capacitively coupled chopper instrumentation amplifier circuit 200 according to the present invention only needs a relatively short time for the initial period. During the initial period from time point to to time point t1, the differential output signal Vod2 can reach the stable predetermined level A*V1 quickly (considering that a predetermined gain of capacitively coupled chopper instrumentation amplifier 200 is equal to the predetermined gain of capacitively coupled chopper instrumentation amplifier 100). According to the present invention, the time to reach the steady state of the differential output signal can be greatly shortened compared to the prior art, and the operating efficiency of the capacitively coupled chopper instrumentation amplifier circuit can be improved.

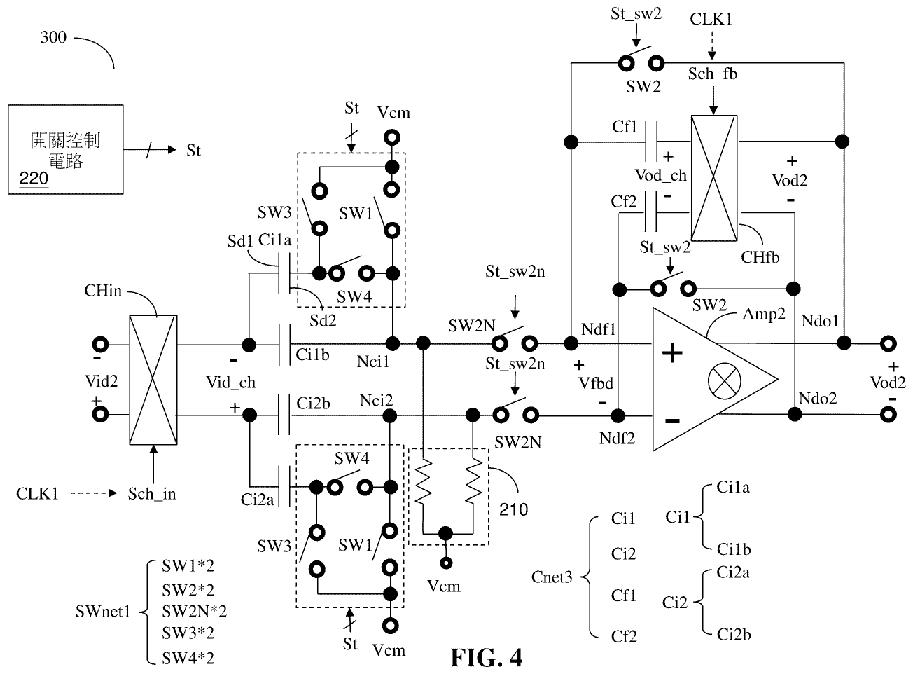

Please refer to FIG. 4, which is a schematic diagram showing an embodiment of a capacitively coupled chopper instrumentation amplifier according to the present invention. As shown in FIG. 4, the capacitively coupled chopper instrumentation amplifier 300 includes an input chopping unit CHin, a feedback chopping unit CHfb, a capacitor feedback network Cnet3, a fully differential amplifier Amp2, a common-mode circuit 210, a switch circuit SWnet1 and switch control circuit 220. The capacitor feedback network Cnet3 includes a pair of differential input capacitors Ci1, Ci2 and a pair of differential feedback capacitors Cf1, Cf2. Compared with the embodiment shown in FIG. 2, this embodiment shown in FIG. 4 shows that the differential input capacitor Ci1 includes a first input capacitor Ci1a and a second input capacitor Ci1b, and the differential input capacitor Ci2 includes a first input capacitor Ci2a and a second input capacitor Ci1b. In addition, in this embodiment shown in FIG. 4, the capacitively coupling chopper instrumentation amplifier 300 further includes a switch circuit SWnet1 and a switch control circuit 220.

As shown in FIG. 4, the switch control circuit 220 is used to generate a timing control signal St to control the switch circuit SWnet1. The switch circuit SWnet1 is used to switch a plurality of switches therein according to the timing control signal St, so as to switch electrical connection states of the first input capacitor Ci1a, Ci2a and the second input capacitor Ci1b, Ci2b of each of the differential input capacitors Ci1, Ci2 between the input chopping unit CHin and the corresponding differential feedback capacitor Cf1 or Cf2 during the initial period, thereby reducing the gain between the differential output signal Vod2 and the differential input signal Vid2 during the initial period.

The plurality of switches of the switch circuit SWnet1 includes a pair of first switches SW1, a pair of second switches SW2, a pair of inverse second switches SW2N, a pair of third switches SW3 and a pair of fourth switches SW4. As shown in FIG. 4, each of the first switch SW1 is coupled between the predetermined common-mode voltage Vcm and a corresponding common-mode input terminal Nci1 or Nci2. Each of the second switch SW2 is coupled between a corresponding differential feedback terminal Ndf1 or Ndf2 and a corresponding differential output terminal Ndo1 or Ndo2. Each of the inverse second switch SW2N is coupled between the corresponding differential feedback terminal Ndf1 or Ndf2 and the corresponding common-mode input terminal Nci1 or Nci2, wherein the inverse second switch SW2N and the second switch SW2 operate inversely to each other. Each of the third switch SW3 is coupled to the predetermined common-mode voltage Vcm and a second side Sd2 of the corresponding first input capacitor Ci1a or Ci1b opposite to a first side Sd1 coupled to the input chopping unit CHin. Each of the fourth switch SW4 is coupled between the corresponding second side Sd2 and the corresponding common-mode input terminal Nci1 or Nci2. The detailed coupling relation of the plurality of switches of the switch circuit SWnet1 is shown in FIG. 4, which will not be repeated here.

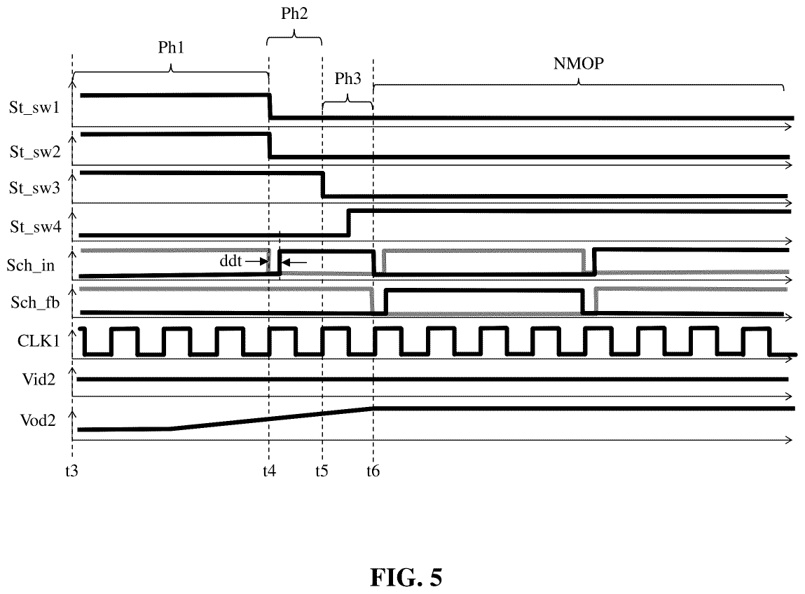

Please still refer to FIG. 4, and refer to FIG. 5 at the same time. FIG. 5 is a schematic diagram showing related signal waveforms of the capacitively coupled chopper instrumentation amplifier during the initial period according to the present invention. In one embodiment, the initial period indicates that the capacitively coupled chopper instrumentation amplifier circuit 300 begins receiving the input signal or just switches to a channel for receiving the input signal. For example, the capacitively coupled chopper instrumentation amplifier circuit 300 is applied to a voltage sensing circuit of a high-voltage battery. The initial period indicates that when the battery voltage is just connected to the capacitively coupled chopper instrumentation amplifier circuit 300, the initial period of the capacitively coupled chopping instrumentation amplifier circuit 300 according to the present invention includes, for example, a first phase Ph1, a second phase Ph2 and a third phase Ph3.

In the first phase Ph1, during the period from a time point t3 to a time point t4 as shown in FIG. 5, an input chopping signal Sch_in is generated based on the clock signal CLK1, and controls the input chopping unit CHin to keep forward conduction; a feedback chopping signal Sch_fb is generated based on the clock signal CLK1 to control the feedback chopping unit CHfb to keep forward conduction; moreover, the switch control circuit 220 controls the pair of the first switches SW1 to be turned ON through a first signal ST_sw1 of the timing control signal St, the switch control circuit 220 controls the pair of the second switches SW2 to be turned ON through a second signal ST_sw2 of the timing control signal St (an inverse second signal ST_sw2n controls the pair of the inverse second switches SW2N to be turned OFF), the switch control circuit 220 controls the pair of third the switches SW3 to be turned ON through a third signal ST_sw3 of the timing control signal St, and the switch control circuit 220 controls the pair of the fourth switches SW4 to be turned OFF through a fourth signal ST_sw4 of the timing control signal St. Through the operation of the input chopping unit Chin, the feedback chopping unit CHfb and the aforementioned plurality of switches (the pair of the first switches SW1, the pair of the second switches SW2, the pair of the inverse second switches SW2N, the pair of the third switches SW3 and the pair of the fourth switches SW4), the differential input signal Vid2 is sampled and hold (stored) in the pair of differential input capacitors Ci1 and Ci2, and the differential feedback capacitance is reset. The first phase Ph1 indicates the initial stage of switching voltage of the differential input signal Vid2, and in the first phase Ph1, the pair of inverse second switches SW2N is turned OFF to avoid output saturation of the capacitively coupled chopper instrumentation amplifier 300.

In the second phase Ph2, during the period from a time point t4 to a time point t5 as shown in FIG. 5, the input chopping signal Sch_in controls the input chopping unit CHin to switch to cross conduction, and the feedback chopping signal Sch_fb controls the feedback chopping unit CHfb to keep forward conduction. Moreover, in the second phase PH2, the switch control circuit 220 controls the pair of the first switches SW1 to be switched (turned) OFF through the first signal ST_sw1 of the timing control signal St, the switch control circuit 220 controls the pair of the second switches SW2 to be switched (turned) OFF through the second signal ST_sw2 of the timing control signal St (the inverse second signal ST_sw2n controls the pair of the inverse second switches SW2N to be switched ON), the switch control circuit 220 controls the pair of the third switches SW3 to be kept ON through the third signal ST_sw3 of the timing control signal St, and the switch control circuit 220 controls the pair of the fourth switches SW4 to be kept OFF through the fourth signal ST_sw4 of the timing control signal St. Through the operations of the input chopping unit Chin, the feedback chopping unit CHfb and the aforementioned plurality of switches (the pair of the first switches SW1, the pair of the second switches SW2, the pair of the inverse second switches SW2N, the pair of the third switches SW3 and the pair of the fourth switches SW4), the gain is adjusted to twice the second input capacitance of the second input capacitor Ci1b, Ci2b (second input capacitor Ci1b and second input capacitor Ci2b are the same kind of capacitor, have the same second input capacitance) divided by the differential feedback capacitance as the adjusted gain. In the second phase Ph2, the gain (adjusted gain) between the differential output signal Vod2 and the differential input signal Vid2 is reduced by reducing the differential input capacitance, so as to avoid the output saturation of the capacitively coupled chopper instrumentation amplifier 200, wherein the adjusted gain is lower than the predetermined gain. Furthermore, as shown in the waveform of the differential output signal Vod2 in FIG. 5, the level of differential output signal Vod2 rises in a way of avoiding output saturation.

In a preferred embodiment, after the end of the first phase Ph1, during the beginning of the second phase Ph2, there is a dead time ddt after the end of forward conduction and before switching to cross conduction of the input chopping unit CHin. During the dead time, the input chopping unit CHin is in an OFF state, neither forward conduction nor cross conduction.

In a preferred embodiment, in the third phase Ph3, the switch control circuit 220 ends the initial period after the capacitively coupled chopper instrumentation amplifier circuit 300 operates in a steady state to start a normal operation NMOP. Meanwhile, the steady state means that the differential output signal Vod2 of the capacitively coupled chopper instrumentation amplifier 300 is stabled and equal to the differential input signal Vid2 multiplied by the predetermined gain of the capacitively coupled chopper instrumentation amplifier 300.

In the third phase, during the period from time point t5 to time point t6 as shown in FIG. 5, the input chopping signal Sch_in controls the input chopping unit CHin to keep cross conduction, and the feedback chopping signal Sch_fb controls the feedback chopping unit CHfb keep forward conduction. Moreover, the switch control circuit 220 controls the pair of the first switches SW1 to be kept OFF through the first signal ST_sw1 of the timing control signal St, the switch control circuit 220 controls the pair of the switches SW2 to be kept OFF through the second signal ST_sw2 of the timing control signal St (the inverse second signal ST_sw2n controls the pair of the inverse second switches SW2N to be kept ON), the switch control circuit 220 controls the pair of the third switches SW3 to be switched OFF through the third signal ST_sw3 of the timing control signal St, and after the pair of the third switches is switched OFF, the switch control circuit 220 controls the pair of the fourth switches SW4 to be switched ON through the fourth signal ST_sw4 of the timing control signal St. Through the operation of the input chopping unit Chin, the feedback chopping unit CHfb and the aforementioned plurality of switches (the pair of the first switches SW1, the pair of the second switches SW2, the pair of the third switches SW3 and the pair of the fourth switches SW4), the first input capacitor Ci1a and the second input capacitor Ci1b are electrically connected in parallel to form the differential input capacitor Ci1, the first input capacitor Ciab and the second input capacitor Ci2b are electrically connected in parallel to form the differential input capacitor Ci2, and the initial period is ended to start the normal operation NMOP. The adjusted gain in the initial period is lower than the predetermined gain, so as to avoid the output saturation of the capacitively coupled chopper instrumentation amplifier 300.

In a preferred embodiment, during the initial period, the capacitively coupled chopper instrumentation amplifier 300 reduces the gain to half the predetermined gain of the capacitively coupled chopper instrumentation amplifier 300 during normal operation NMOP.

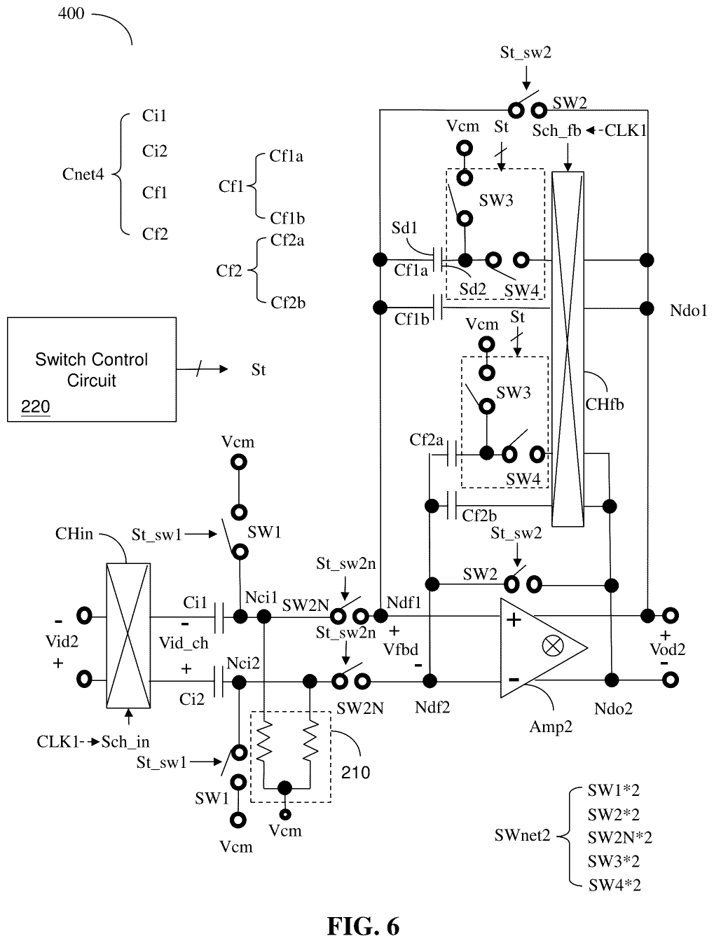

Please refer to FIG. 6. FIG. 6 is a schematic diagram showing an embodiment of a capacitively coupled chopper instrumentation amplifier according to the present invention. As shown in FIG. 6, the capacitively coupled chopper instrumentation amplifier 400 includes the input chopping unit CHin, the feedback chopping unit CHfb, a capacitor feedback network Cnet4, a fully differential amplifier Amp2, the common-mode circuit 210, a switch circuit SWnet2 and the switch control circuit 220. The capacitor feedback network Cnet4 includes the pair of the differential input capacitors Ci1, Ci2 and the pair of the differential feedback capacitors Cf1, Cf2. Compared with the embodiment shown in FIG. 4, the embodiment shown in FIG. 6 indicates that the differential feedback capacitor Cf1 includes a first feedback capacitor Cfla and a second feedback capacitor Cf1b, and the differential feedback capacitor Cf2 includes a first feedback capacitor Cf2a and a second feedback capacitor Cf2b. Meanwhile, in the embodiment shown in FIG. 6, the capacitively coupled chopper instrumentation amplifier 400 includes the switch circuit SWnet2.

As shown in FIG. 6, the switch control circuit 220 is used to generate a timing control signal St to control the switch circuit SWnet2. The switch circuit SWnet2 is used to switch a plurality of switches therein according to the timing control signal St, so as to switch electrical connection states of the first feedback capacitor Cfla, Cf2a and the second feedback capacitor Cf1b, Cf2b of each of the differential feedback capacitors Cf1, Cf2, the feedback chopping unit CHfb and corresponding differential input capacitor Ci1 or Ci2 during the initial period, thereby reducing the gain between the differential output signal Vod2 and the differential input signal Vid2.

The plurality of switches of the switch circuit SWnet2 includes the pair of the first switches SW1, the pair of the second switches SW2, the pair of the inverse second switches SW2N, the pair of the third switches SW3 and the pair of the fourth switches SW4. As shown in FIG. 6, each of the first switch SW1 is coupled between the predetermined common-mode voltage Vcm and the corresponding common-mode input terminal Nci1 or Nci2, each of the second switch SW2 is coupled between the corresponding differential feedback terminal Ndf1 or Ndf2 and the corresponding differential output terminal Ndo1 or Ndo2, each of the inverse second switch SW2N is coupled between the corresponding differential feedback terminal Ndf1 or Ndf2 and the corresponding common-mode input terminal Nci1 or Nci2, wherein the inverse second switch SW2N and the second switch SW2 operate inversely to each other. Each of the third switch SW3 is coupled between the predetermined common-mode voltage Vcm and a second side Sd2 of the corresponding first feedback capacitor Cfla or Cf2a opposite to the first side Sd1 coupled to the differential feedback terminal Ndf1 or Ndf2. Each of the fourth switch SW4 is coupled between the corresponding second side Sd2 and feedback chopping unit CHfb. The detailed coupling relation of the plurality of switches of the switch circuit SWnet2 is shown in FIG. 6, which will not be repeated here.

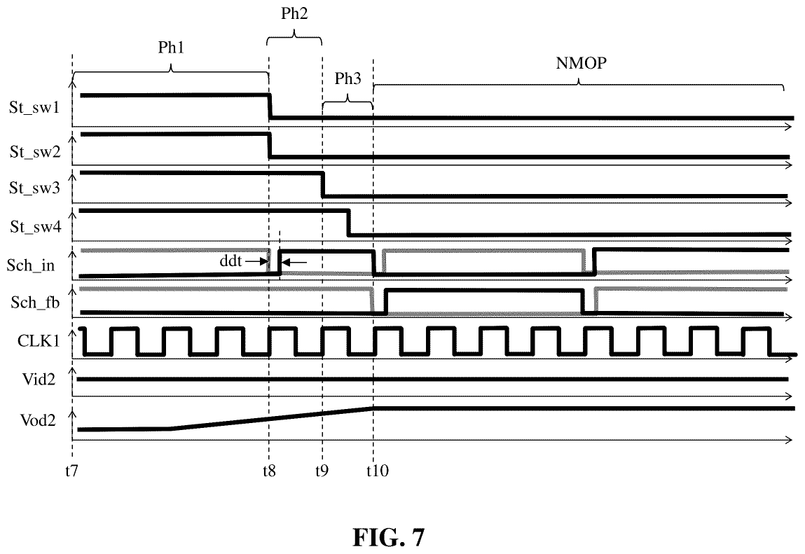

Please still refer to FIG. 6, and refer to FIG. 7 at the same time. FIG. 7 is a schematic diagram showing related signal waveforms of the capacitively coupled chopper instrumentation amplifier circuit during the initial period according to the present invention. In one embodiment, the initial period indicates that the capacitively coupled chopper instrumentation amplifier circuit 400 begins receiving the input signal or just switches to a channel for receiving the input signal. For example, the capacitively coupled chopper instrumentation amplifier circuit 400 is applied to the voltage sensing circuit of the high-voltage battery. The initial period indicates that when the battery voltage is just connected to the capacitively coupled chopper instrumentation amplifier circuit 400, the initial period of the capacitively coupled chopping instrumentation amplifier circuit 400 according to the present invention includes, for example, a first phase Ph1, a second phase Ph2 and a third phase Ph3.

In the first phase Ph1, during the period from a time point t7 to a time point t8 as shown in FIG. 7, the input chopping signal Sch_in is generated based on the clock signal CLK1 to control the input chopping unit CHin to keep forward conduction. The feedback chopping signal Sch_fb is generated based on the clock signal CLK1 to control the feedback chopping unit CHfb to keep forward conduction. Moreover, in the first phase Ph1, the switch control circuit 220 controls the pair of the first switches SW1 to be turned ON through the first signal ST_sw1 of the timing control signal St, the switch control circuit 220 controls the pair of the second switches SW2 to be turned ON through the second signal ST_sw2 of the timing control signal St (the inverse second signal ST_sw2n controls the pair of the inverse second switches SW2N to be turned OFF), the switch control circuit 220 controls the pair of the third switches SW3 to be turned ON through the third signal ST_sw3 of the timing control signal St, and the switch control circuit 220 controls the pair of the fourth switches SW4 to be turned ON through the fourth signal ST_sw4 of the timing control signal St. Through the operation of the input chopping unit Chin, the feedback chopping unit CHfb and the aforementioned plurality of switches (the pair of the first switches SW1, the pair of the second switches SW2, the pair of the inverse second switches SW2N, the pair of the third switches SW3 and the pair of the fourth switches SW4), the differential input signal Vid2 is sampled and stored in the pair of differential input capacitors Ci1 and Ci2, and the differential feedback capacitance is reset. The first phase Ph1 indicates the initial stage of switching voltage of the differential input signal Vid2, and in the first phase Ph1, the pair of inverse second switches SW2N is turned OFF to avoid output saturation of the capacitively coupled chopper instrumentation amplifier 400.

In the second phase Ph2, during the period from a time point t8 to a time point t9 as shown in FIG. 7, the input chopping signal Sch_in controls the input chopping unit CHin to switch to cross conduction, and the feedback chopping signal Sch_fb controls the feedback chopping unit CHfb to keep forward conduction. Moreover, in the second phase Ph2, the switch control circuit 220 controls the pair of the first switches SW1 to be switched OFF through the first signal ST_sw1 of the timing control signal St, the switch control circuit 220 controls the pair of the second switches SW2 to be switched OFF through the second signal ST_sw2 of the timing control signal St, the switch control circuit 220 controls the pair of the third switches SW3 to be kept ON through the third signal ST_sw3 of the timing control signal St, and the switch control circuit 220 controls the pair of the fourth switches SW4 to be kept ON through the fourth signal ST_sw4 of the timing control signal St. Through the operations of the input chopping unit Chin, the feedback chopping unit CHfb and the aforementioned plurality of switches (the pair of the first switches SW1, the pair of the second switches SW2, the pair of the third switches SW3 and the pair of the fourth switches SW4), the second feedback capacitors Cflb and Cf2b are respectively connected in parallel with the first feedback capacitors Cfla and Cf2a, the gain is adjusted to twice the differential input capacitance (differential input capacitor Ci1 and differential input capacitor Ci2 are the same type of capacitor with the same differential input capacitance) divided by the differential feedback capacitance after the second feedback capacitors Cf1b, Cf2b are respectively connected in parallel with the first feedback capacitors Cf1a, Cf2a. In the second phase Ph2, the gain between the differential output signal Vod2 and the differential input signal Vid2 is reduced by reducing the differential input capacitance, so as to avoid the output saturation of the capacitively coupled chopper instrumentation amplifier 400, wherein the adjusted gain is lower than the predetermined gain. Furthermore, as shown in the waveform of the differential output signal Vod2 in FIG. 7, the level of differential output signal Vod2 rises in a way that avoids output saturation.

In the third phase, during the period from a time point t9 to a time point t10 as shown in FIG. 7, the input chopping signal Sch_in controls the input chopping unit CHin to keep cross conduction, and the feedback chopping signal Sch_fb controls the feedback chopping unit CHfb to keep forward conduction. Moreover, the switch control circuit 220 controls the pair of the first switches SW1 to be kept OFF through the first signal ST_sw1 of the timing control signal St, the switch control circuit 220 controls the pair of the switches SW2 to be kept OFF through the second signal ST_sw2 of the timing control signal St, the switch control circuit 220 controls the pair of the third switches SW3 to be switched OFF through the third signal ST_sw3 of the timing control signal St, and after the pair of the third switches is switched OFF, the switch control circuit 220 controls the pair of the fourth switches SW4 to be switched OFF through the fourth signal ST_sw4 of the timing control signal St. Through the operations of the input chopping unit Chin, the chopping feedback unit CHfb and the aforementioned plurality of switches (the pair of the first switches SW1, the pair of the second switches SW2, the pair of the third switches SW3 and the pair of the fourth switches SW4), so as to use the second feedback capacitor Cf1 as the differential feedback capacitor, and end the initial period to start the normal operation NMOP.

In summary, the present invention reduces the gain to the adjusted gain between the differential output signal and the differential input signal during the initial period of the capacitively coupled chopper instrumentation amplifier, that is, the initial period of receiving the input signal or the initial period of switching the channel of the receiving signal. For example, using a plurality of switches to switch the electrical connection states of differential input capacitors and/or differential feedback capacitors to reduce the gain related to the predetermined gain to avoid output saturation of the capacitively coupled chopper instrumentation amplifier, and to shorten the time to reach a predetermined output in the initial period, thereby improving the operating efficiency of the capacitively coupled chopper instrumentation amplifier.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a metal silicide layer, may be added. For another example, the lithography process step is not limited to the mask technology but it can also include electron beam lithography, immersion lithography, etc. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A capacitively coupled chopper instrumentation amplifier, comprising:
an input chopping unit, which is configured to operably chop a differential input signal based on a clock signal to generate a chopped differential input signal;
a feedback chopping unit, which is configured to operably chop a differential output signal based on the clock signal to generate a chopped differential feedback signal;
a capacitor feedback network, which includes a pair of differential input capacitors and a pair of differential feedback capacitors, wherein each of the differential input capacitors is connected to a corresponding of the differential feedback capacitors in series between the input chopping unit and the feedback chopping unit, wherein the input chopping unit, the feedback chopping unit, and the capacitor feedback network are coupled to convert a differential difference of the chopped differential output signal and the chopped differential input signal to generate a differential feedback signal by a switching capacitor voltage division method; and
a fully differential amplifier, which is configured to operably amplify the differential feedback signal to generate the differential output signal;
wherein a gain between the differential output signal and the differential input signal is equal to twice a differential input capacitance of the differential input capacitor divided by a differential feedback capacitance of the differential feedback capacitor;
wherein during a normal operation, the gain is a predetermined gain, the differential input capacitance is a predetermined differential input capacitance, and the differential feedback capacitance is a predetermined differential feedback capacitance;
wherein during an initial period, when the input chopping unit receives the differential input signal, the capacitively coupled chopper instrumentation amplifier avoids an output saturation of the capacitively coupled chopper instrumentation amplifier by reducing the gain to an adjusted gain.

2. The capacitively coupled chopper instrumentation amplifier of claim 1, further comprising a common-mode circuit which is coupled to the capacitor feedback network, and is configured to operably regulate a common-mode voltage of the differential feedback signal to a predetermined common-mode voltage.

3. The capacitively coupled chopper instrumentation amplifier of claim 2, wherein the capacitively coupled chopper instrumentation amplifier reduces the gain during the initial period by reducing the differential input capacitance and/or increasing the differential feedback capacitance.

4. The capacitively coupled chopper instrumentation amplifier of claim 3, further comprising:
a switch circuit, which is configured to operably switch a plurality of switches therein during the initial period according to a timing control signal, so as to switch electrical connection states of a first input capacitor and a second input capacitor of each of the differential input capacitor between the input chopping unit and the corresponding differential feedback capacitor, thereby reducing the gain during the initial period; and
a switch control circuit, which is configured to operably generate the timing control signal to control the switch circuit.

5. The capacitively coupled chopper instrumentation amplifier of claim 4, wherein the plurality of switches includes:
a pair of first switches, wherein each of the first switches is coupled between the predetermined common-mode voltage and a corresponding common-mode input terminal;
a pair of second switches, wherein each of the second switches is coupled between a corresponding differential feedback terminal and a corresponding differential output terminal;
a pair of inverse second switches, wherein each of the inverse second switches is coupled between the corresponding differential feedback terminal and the corresponding common-mode input terminal, wherein the inverse second switch and the second switch operate inversely to each other;
a pair of third switches, wherein each of the third switches is coupled between the predetermined common-mode voltage and a second side of the corresponding first input capacitor opposite to a first side coupled to the input chopping unit; and
a pair of fourth switches, wherein each of the fourth switches is coupled between the corresponding second side and the corresponding common-mode input terminal.

6. The capacitively coupled chopper instrumentation amplifier of claim 5, wherein the initial period includes:
a first phase, wherein both the input chopping unit and the feedback chopping unit keep forward conduction, and the switch control circuit controls the pair of the first switches to be turned ON, the pair of the second switches to be turned ON, the pair of the third switches to be turned ON, and the pair of the fourth switches to be turned OFF through the timing control signal, so as to sample and hold the differential input signal in the pair of differential input capacitors, and reset the differential feedback capacitance;
a second phase, wherein the input chopping unit switches to cross conduction, the feedback chopping unit keeps forward conduction, and the switch control circuit controls the pair of the first switches to be switched OFF, the pair of the second switches to be switched OFF, the pair of the third switches to be kept ON, and the pair of the fourth switches to be kept OFF through the timing control signal, so that the adjusted gain is twice a second input capacitance of the second input capacitor divided by the differential feedback capacitance; and
a third phase, wherein the input chopping unit keeps cross conduction, the feedback chopping unit keeps forward conduction, and the switch control circuit controls the pair of the first switches to be kept OFF, the pair of the second switches to be kept OFF, the pair of the third switches to be switched OFF through the timing control signal, and the pair of the fourth switches is switched ON after the pair of third switches is switched OFF, so as to electrically connect the first input capacitor and the second input capacitor in parallel to form the differential input capacitance to end the initial period to start the normal operation;
wherein the adjusted gain in the initial period is lower than the predetermined gain, so as to avoid the output saturation of the capacitively coupled chopper instrumentation amplifier.

7. The capacitively coupled chopper instrumentation amplifier of claim 6, wherein after the end of the first phase, during the beginning of the second phase, there is a dead time after forward conduction and before switching to cross conduction of the input chopping unit.

8. The capacitively coupled chopper instrumentation amplifier of claim 6, wherein in the third phase, the switch control circuit ends the initial period after the capacitively coupled chopper instrumentation amplifier circuit operates in a steady state to start the normal operation.

9. The capacitively coupled chopper instrumentation amplifier of claim 6, wherein in the initial period, the adjusted gain is equal to half of the predetermined gain.

10. The capacitively coupled chopper instrumentation amplifier of claim 3, further comprising:
a switch circuit, which is configured to operably switch a plurality of switches therein according to a timing control signal, so as to switch electrical connection states of a first feedback capacitor and a second feedback capacitor of each of the differential feedback capacitor between the feedback chopping unit and the corresponding differential input capacitor during the initial period, thereby reducing the gain; and
a switch control circuit, which is configured to operably generate the timing control signal to control the switch circuit.

11. The capacitively coupled chopper instrumentation amplifier of claim 10, wherein the plurality of switches includes:
a pair of first switches, wherein each of the first switches is coupled between the predetermined common-mode voltage and a corresponding common-mode input terminal;
a pair of second switches, wherein each of the second switches is coupled between a corresponding differential feedback terminal and a corresponding differential output terminal;
a pair of inverse second switches, wherein each of the inverse second switches is coupled between the corresponding differential feedback terminal and the corresponding common-mode input terminal, wherein the inverse second switch and the second switch operate inversely to each other;
a pair of third switches, wherein each of the third switches is coupled between the predetermined common-mode voltage and a second side of the corresponding first feedback capacitor opposite to the first side coupled to the differential feedback terminal; and
a pair of fourth switches, wherein each of the fourth switches is coupled between the corresponding second side and the corresponding common-mode input terminal.

12. The capacitively coupled chopper instrumentation amplifier of claim 11, wherein the initial period comprises:
a first phase, wherein both the input chopping unit and the feedback chopping unit keep forward conduction, and the switch control circuit controls the pair of first switches to be turned ON, the pair of second switches to be turned ON, the pair of third switches to be turned ON, and the pair of fourth switches to be turned OFF through the timing control signal, so as to sample and hold the differential input signal in the pair of differential input capacitors, and reset the differential feedback capacitance;
a second phase, wherein the input chopping unit switches to cross conduction, the feedback chopping unit keeps forward conduction, and the switch control circuit controls the pair of the first switches to be switched OFF, the pair of the second switches to be switched OFF, the pair of the third switches to be kept ON, and the pair of the fourth switches switched to be switched ON through the timing control signal, so as to electrically connect the second feedback capacitor with the first feedback capacitor in parallel, and the adjusted gain is twice the differential input capacitance divided by the differential feedback capacitance after the second feedback capacitance is electrically connected in parallel with the first feedback capacitance; and
a third phase, wherein the input chopping unit keeps cross conduction, the feedback chopping unit keeps forward conduction, and the switch control circuit controls the pair of the first switches to be kept OFF, the pair of the second switches to be kept OFF, the pair of the third switches to be switched OFF, and the pair of the fourth switches to be switched OFF through the timing control signal, so as to end the parallel connection between the second feedback capacitor and the first feedback capacitor, and end the initial period to start the normal operation;
wherein the adjusted gain in the initial period is lower than the predetermined gain, so as to avoid the output saturation of the capacitively coupled chopper instrumentation amplifier.

13. The capacitively coupled chopper instrumentation amplifier of claim 12, wherein after the end of the first phase, during the beginning of the second phase, there is a dead time after forward conduction and before switching to cross conduction of the input chopping unit.

14. The capacitively coupled chopper instrumentation amplifier of claim 12, wherein in the third phase, the switch control circuit ends the initial period after the capacitively coupled chopper instrumentation amplifier circuit operates in a steady state to start the normal operation.

15. The capacitively coupled chopper instrumentation amplifier of claim 12, wherein in the initial period, the adjusted gain is equal to half of the predetermined gain.

16. A control method of a capacitively coupled chopper instrumentation amplifier, comprising steps of:
chopping a differential input signal based on a clock signal to generate a chopped differential input signal;
chopping a differential output signal based on the clock signal to generate a chopped differential feedback signal;
providing a pair of differential input capacitors and a pair of differential feedback capacitors, wherein each of the differential input capacitors is connected to a corresponding one of the differential feedback capacitors in series, and converting a differential difference of the chopped differential output signal and the chopped differential input signal to generate a differential feedback signal by a switching capacitor voltage division method; and
avoiding output saturation of the capacitively coupled chopper instrumentation amplifier by reducing a gain to an adjusted gain between the differential output signal and the differential input signal during an initial period;
wherein the gain is equal to twice a differential input capacitance of the differential input capacitor divided by a differential feedback capacitance of the differential feedback capacitor;
wherein during a normal operation, the gain is a predetermined gain, the differential input capacitance is a predetermined differential the input capacitance, and feedback capacitance is a predetermined differential differential feedback capacitance.

17. The control method of the capacitively coupled chopper instrumentation amplifier of claim 16, further comprising a step of: regulating the common-mode voltage of the differential feedback signal to a predetermined common-mode voltage.

18. The control method of the capacitively coupled chopper instrumentation amplifier of claim 17, wherein the step of avoiding output saturation of the capacitively coupled chopper instrumentation amplifier by reducing the gain to the adjusted gain between the differential output signal and the differential input signal during the initial period includes: reducing the gain by reducing the differential input capacitance and/or increasing the differential feedback capacitance.

19. The control method of the capacitively coupled chopper instrumentation amplifier of claim 18, further comprising a step of:
switching a plurality of switches during the initial period according to a timing control signal, so as to switch electrical connection states of a first input capacitor and a second input capacitor of each of the differential input capacitor between an input chopping unit and the corresponding differential feedback capacitor, thereby reducing the gain during the initial period.

20. The control method of the capacitively coupled chopper instrumentation amplifier of claim 19, wherein the plurality of switches includes:
a pair of first switches, wherein each of the first switches is coupled between the predetermined common-mode voltage and a corresponding common-mode input terminal;
a pair of second switches, wherein each of the second switches is coupled between corresponding differential feedback terminal and a corresponding differential output terminal;
a pair of inverse second switches, wherein each of the inverse second switches is coupled between the corresponding differential feedback terminal and the corresponding common-mode input terminal, wherein the inverse second switch and the second switch operate inversely to each other;
a pair of third switches, wherein each of the third switches is coupled between the predetermined common-mode voltage and a second side of the corresponding first input capacitor opposite to a first side coupled to the input chopping unit; and
a pair of fourth switches, wherein each of the fourth switches is coupled between a corresponding second side and the corresponding common-mode input terminal.

21. The control method of the capacitively coupled chopper instrumentation amplifier of claim 20, wherein the step of avoiding output saturation of the capacitively coupled chopper instrumentation amplifier by reducing the gain between the differential output signal and the differential input signal during the initial period includes:
in a first phase, keeping both the input chopping unit and a feedback chopping unit forward conduction, and controlling the pair of first switches to be turned ON, the pair of second switches to be turned ON, the pair of third switches to be turned ON, and the pair of fourth switches to be turned OFF through the timing control signal, so as to sample and hold the differential input signal in the pair of differential input capacitors, and resetting the differential feedback capacitance;
in a second phase, switching the input chopping unit to cross conduction, keeping the feedback chopping unit forward conduction, and controlling the pair of the first switches to be switched OFF, the pair of the second switches to be switched OFF, the pair of the third switches to be kept ON, and the pair of the fourth switches to be kept OFF through the timing control signal, so that the adjusted gain is twice a second input capacitance of the second input capacitor divided by the differential feedback capacitance; and
in a third phase, keeping the input chopping unit cross conduction, keeping the feedback chopping unit forward conduction, and controlling the pair of the first switches to be kept OFF, the pair of the second switches to be kept OFF, and the pair of the third switches to be switched OFF through the timing control signal, the pair of the fourth switches to be switched ON after the pair of the third switches are switched OFF, so as to electrically connect the first input capacitor and the second input capacitor in parallel to form the differential input capacitance to end the initial period to start the normal operation;
wherein the adjusted gain in the initial period is lower than the predetermined gain, so as to avoid the output saturation of the capacitively coupled chopper instrumentation amplifier.

22. The control method of the capacitively coupled chopper instrumentation amplifier of claim 21, wherein after the end of the first phase, during the beginning of the second phase, there is a dead time after forward conduction and before switching to cross conduction of the input chopping unit.

23. The control method of the capacitively coupled chopper instrumentation amplifier of claim 21, wherein in the third phase, the initial period is ended after the capacitively coupled chopper instrumentation amplifier circuit operates in a steady state to start the normal operation.

24. The control method of the capacitively coupled chopper instrumentation amplifier of claim 21, wherein in the initial period, the adjusted gain is reduced to half of a predetermined gain during the normal operation.

25. The control method of the capacitively coupled chopper instrumentation amplifier of claim 18, further comprising a step of:
switching a plurality of switches according to a timing control signal, so as to switch electrical connection states of a first feedback capacitor and a second feedback capacitor of each of the differential feedback capacitor between the feedback chopping unit and the corresponding differential input capacitor during the initial period, thereby reducing the gain.

26. The control method of the capacitively coupled chopper instrumentation amplifier of claim 25, wherein the plurality of switches include:
a pair of first switches, wherein each of the first switches is coupled between the predetermined common-mode voltage and a corresponding common-mode input terminal;
a pair of second switches, wherein each of the second switches is coupled between a corresponding differential feedback terminal and a corresponding differential output terminal;
a pair of inverse second switches, wherein each of the inverse second switches is coupled between the corresponding differential feedback terminal and the corresponding common-mode input terminal, wherein the inverse second switch and the second switch operate inversely to each other;
a pair of third switches, wherein each of the third switches is coupled to the predetermined common-mode voltage and a second side of the corresponding first feedback capacitor opposite to the first side coupled to the differential feedback terminal; and
a pair of fourth switches, wherein each of the fourth switches is coupled between the corresponding second side and the corresponding feedback chopping unit.

27. The control method of the capacitively coupled chopper instrumentation amplifier of claim 26, wherein the step of avoiding output saturation of the capacitively coupled chopper instrumentation amplifier by reducing the gain between the differential output signal and the differential input signal during the initial period includes:
In a first phase, keeping both the input chopping unit and the feedback chopping unit forward conduction, and controlling the pair of the first switches to be turned ON, the pair of the second switches to be turned ON, the pair of the third switches to be turned ON, and the pair of the fourth switches to be turned ON through the timing control signal, so as to sample and hold the differential input signal in the pair of differential input capacitors, and resetting the differential feedback capacitance;
in a second phase, switching the input chopping unit to cross conduction, keeping the feedback chopping unit forward conduction, and controlling the pair of the first switches to be switched OFF, the pair of the second switches to be switched OFF, the pair of the third switches to be kept ON, and the pair of the fourth switches to be kept ON through the timing control signal, so as to connect the second feedback capacitor with the first feedback capacitor in parallel, and the adjusted gain is twice the differential input capacitance divided by the differential feedback capacitance after the second feedback capacitance is connected in parallel with the first feedback capacitance; and
in a third phase, keeping the input chopping unit cross conduction, keeping the feedback chopping unit forward conduction, and controlling the pair of the first switches to be kept OFF, the pair of the second switches to be kept OFF, and the pair of the third switches to be switched OFF through the timing control signal, the pair of the fourth switches to be switched OFF after the pair of the third switches are switched OFF, so as to finish the parallel connection of the second feedback capacitor and the first feedback capacitor to end the initial period to start the normal operation;
wherein the adjusted gain in the initial period is lower than the predetermined gain, so as to avoid the output saturation of the capacitively coupled chopper instrumentation amplifier.

28. The control method of the capacitively coupled chopper instrumentation amplifier of claim 27, wherein after the end of the first phase, during the beginning of the second phase, there is a dead time after forward conduction and before switching to cross conduction of the input chopping unit.

29. The control method of the capacitively coupled chopper instrumentation amplifier of claim 27, wherein in the third phase, the initial period is ended after the capacitively coupled chopper instrumentation amplifier circuit operates in a steady state to start the normal operation.

30. The control method of the capacitively coupled chopper instrumentation amplifier of claim 27, wherein in the initial period, the adjusted gain is half of the predetermined gain.
